(19) United States
(12) Patent Application Publication
(10) Pub. No.: US 2007/0052351 A1
(43) Pub. Date: Mar. 8, 2007

(54) Organic light emitting devices comprising hole transporting layer doped stepwise and preparation method thereof

(76) Inventors: Tae-Whan Kim, Seoul (KR); Hui-Won Yang, Cheongju-si (KR)

Correspondence Address: CANTOR COLBURN, LLP, 55 GRIFFIN ROAD SOUTH, BLOOMFIELD, CT, 06002, US

(21) Appl. No.: 11/517,099

(22) Filed: Sep. 7, 2006

(30) Foreign Application Priority Data
Sep. 8, 2005 (KR) 10-2005-0083544

(51) Int. Cl. H01L 51/52; H01L 51/54

(52) U.S. Cl. 313/506; 313/504; 427/66; 428/690; 428/917; 428/212

(57) ABSTRACT

An organic light emitting device includes a hole transporting layer including two or more regions in which concentration of an impurity doped into a host forms a stepwise concentration gradient.

This application claims priority to Korean Patent Application No. 10-2005-0083544, filed on Sep. 8, 2005, and all the benefits accruing therefrom under 35 U.S.C. § 119, the contents of which in its entirety are herein incorporated by reference.

### BACKGROUND OF THE INVENTION

(a) Field of the Invention

The present invention relates to an organic light emitting device and a manufacturing method thereof in which luminous efficiency and color stability are enhanced and a driving voltage is reduced.

(b) Description of the Related Art

Recent trends show that the display area of display devices is increasing. As the display area increases the demand for a flat display device which takes up little space is also increasing. Correspondingly, the technology of an organic light emitting device as one type of such a flat display device is developing rapidly.

In general, mobility of holes through an organic material is greater than mobility of electrons because of ionization potential and electron affinity, so holes move more easily than electrons. Because of this imbalance in electron and hole mobility, holes tend to move through the organic material of the organic light emitting device without recombining with an electron. The holes then accumulate around the source of the electrons, usually an electron adding layer, where their recombination does not contribute to luminosity. When the recombination of the hole and the electron do not produce a photon of the desired wavelength, it is called a non-emissive recombination. That is, since the mobility of holes is hundreds to thousands of times higher than the mobility of electrons, the mobility of holes must be decreased in order for the holes and electrons to be recombined in an emission layer, thereby maximizing luminous efficiency.

In a comparative example of an organic light emitting device, an impurity was uniformly doped into a hole transporting layer so as to improve the luminous efficiency and the stability of the device by decreasing hole mobility. Doping of an impurity into the hole transporting layer functions as a trap for the holes, or hole trap, due to different highest occupied molecular orbital (“HOMO”) energy levels of the impurity and the constituent material of the hole transporting layer. The effect of the hole trap created by the impurity is to reduce the mobility of holes and increase the electron density at the interface between a hole transporting layer and an emission layer. The hole trap also functions to suppress the generation of positive ions in the emission layer, thereby extending the life span of the light emitting device. Moreover, the hole trap plays an important role in improving the luminous efficiency of the device as a location for the emissive recombination of electrons and holes.

However, the hole trap created by the impurity has a problem in that it generates an inner electric field having a direction opposite to an outer electric field applied by a hole adding layer and an electron adding layer of the organic light emitting device. As a result, injection and transportation characteristics of holes and electrons are deteriorated, thereby necessitating an increase in a driving voltage of the organic light emitting device. Therefore, development of a device having a layer structure in which holes are efficiently injected and the electron-hole recombination efficiency is improved while a driving voltage of the device is reduced is required.

### BRIEF SUMMARY OF THE INVENTION

The present invention has been made in an effort to provide an organic light emitting device comprising a hole transporting layer doped stepwise, and a preparation method thereof, having advantages of improved luminous efficiency and color stability and a reduced driving voltage.

An aspect of the present invention is to provide an organic light emitting device and a manufacturing method thereof in which luminous efficiency is enhanced and color stability is obtained while a driving voltage is reduced.

To achieve the above aspect, an exemplary embodiment of the present invention provides an organic light emitting device comprising a hole transporting layer including two or more regions in which concentration of an impurity doped into a host forms a stepwise concentration gradient.

Here, the organic light emitting device may further include: an anode formed on a substrate; an emission layer formed on the hole transporting layer; an electron injecting layer formed on the emission layer; and a cathode formed on the electron injecting layer. The hole transporting layer is formed on the anode.

The hole transporting layer may include an interface region between an anode and a hole transporting region, the hole transporting region, and an interface region between an emission layer and the hole transporting region.

The impurity concentration doped into the interface region between the anode and the hole transporting region may be about 0.5 weight %, the impurity concentration doped into the hole transporting region may be about 1.0 weight %, and the impurity concentration doped into the interface region between the emission layer and the hole transporting region may be about 1.5 weight %.

The thickness of the interface region between the anode and the hole transporting region, the thickness of the hole transporting region, and the thickness of the interface region between the emission layer and the hole transporting region may be about 20 nm, respectively.

The impurity may have a higher highest occupied molecular orbital (“HOMO”) energy level than a HOMO energy level of a material constituting the hole transporting layer.

The impurity may be at least one impurity selected from a group of rubrene, perylene 4-dicyano-methylene-2-methyl-6-4-dimethylami-nostyryl-4H-piran (“DCM1”) and 4-(dicyanomethylene)-2-(1-propyl)6-methy 4H-pyran (“DCJTB”.

Another exemplary embodiment of the present invention provides a manufacturing method of an organic light emitting device including: forming an anode on a substrate; forming a hole transporting layer on the anode; forming an emission layer on the hole transporting layer; forming an electron injecting layer on the emission layer; and forming a cathode on the electron injecting layer. The hole transporting layer in the step 2) of forming a hole transporting layer includes two or more regions formed by deposition in which the concentration of a doped impurity forms a stepwise concentration gradient.

### BRIEF DESCRIPTION OF THE DRAWINGS

FIG. 1 is a schematic diagram of a the layer structure of a comparative example of an organic light emitting device;

FIG. 2 is a schematic diagram illustrating a layer structure of an exemplary embodiment of an organic light emitting device according to the present invention and organic light emitting devices according to comparative examples;

FIG. 3 is a graph illustrating current density measured against voltage of an exemplary embodiment of an organic light emitting device according to the present invention;

FIG. 4 is a graph illustrating luminance measured against voltage of an exemplary embodiment of an organic light emitting device according to the present invention;

FIG. 5 is a graph illustrating luminous efficiency measured against current density of an exemplary embodiment of an organic light emitting device according to the present invention; and

FIG. 6 is a graph of color coordinates of an exemplary embodiment of an organic light emitting device according to the present invention.

### DETAILED DESCRIPTION OF THE INVENTION

The invention now will be described more fully hereinafter with reference to the accompanying drawings, in which embodiments of the invention are shown. This invention may, however, be embodied in many different forms and should not be construed as limited to the embodiments set forth herein. Rather, these embodiments are provided so that this disclosure will be thorough and complete, and will fully convey the scope of the invention to those skilled in the art. Like reference numerals refer to like elements throughout.

It will be understood that when an element is referred to as being “on” another element, it can be directly on the other element or intervening elements may be present therebetween. In contrast, when an element is referred to as being “directly on” another element, there are no intervening elements present. As used herein, the term “and/or” includes any and all combinations of one or more of the associated listed items.

It will be understood that, although the terms first, second, third etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the present invention.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Furthermore, relative terms, such as “lower” or “bottom” and “upper” or “top,” may be used herein to describe one element's relationship to another elements as illustrated in the Figures. It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The exemplary term “lower”, can therefore, encompasses both an orientation of “lower” and “upper,” depending of the particular orientation of the figure. Similarly, if the device in one of the figures is turned over, elements described as “below” or “beneath” other elements would then be oriented “above” the other elements. The exemplary terms “below” or “beneath” can, therefore, encompass both an orientation of above and below.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

Embodiments of the present invention are described herein with reference to cross section illustrations that are schematic illustrations of idealized embodiments of the present invention. As such, variations from the shapes of the illustrations as a result, for example, of manufacturing techniques and/or tolerances, are to be expected. Thus, embodiments of the present invention should not be construed as limited to the particular shapes of regions illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present invention.

An exemplary embodiment of the present invention will hereinafter be described in detail with reference to the accompanying drawings.

Before describing the present invention in detail hereinafter, driving principles and a structure of a comparative example of an organic light emitting device will be briefly described.

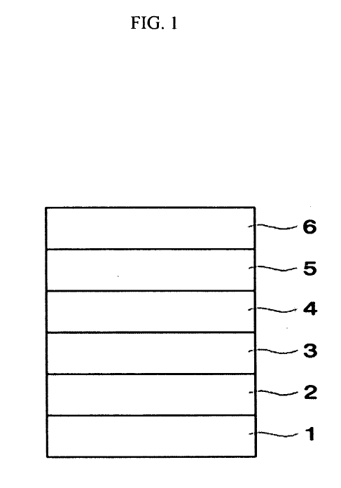

Referring to FIG. 1, when a driving voltage is applied to a hole adding layer known as an anode 1 and an electron adding layer known as a cathode 6, holes and electrons transfer to the emission layer 3 through the hole transporting layer 2 and the electron transporting layer 4, respectively, and the electrons and holes flow into the organic emission layer to generate excitons, which transition from an excited state to a ground state and emit visible light corresponding to the energy difference between the excited state and the ground state. An electron injecting layer 5 may also be optionally included. Using a plurality of pixels, each having the structure described above, a picture or an image may be displayed based on a principle that the visible light emitted from the emission layer in this way is transmitted through a transparent anode electrode.

The anode, which is an electrode for the injection of holes, has a high work function, meaning that the minimum amount of energy it takes to remove an electron from the anode into a vacuum is a relatively large amount. The anode is generally made of a transparent metal oxide so that the emitted light may be passed through the device to an outside. The most widely used hole injecting layer is in an indium tin oxide (“ITO”) electrode.

The emission layer may be formed using a low molecular weight organic material such as tris-(8-hydrozyquinoline)aluminum (“Alq₃”) and anthracene or a high molecular weight organic material such as poly(p-phenylenevinylene) (“PPV”), polythiophene (“PT”), and their derivatives.

A hole transporting layer 2 is interposed between the anode 1 and the emission layer 3; an electron transporting layer 4 and an electron injecting layer 5 are interposed between the emission layer 3 and the cathode 6. This structure enhances the mobility of holes and electrons, respectively, and these layers are made of a low molecular weight or high molecular weight organic material. This structure provides improved quantum efficiency over devices where a cathode and an anode are applied directly to an emission layer. This structure also reduces the driving voltage necessary for injecting carriers (electrons or holes) into the emission layer. In addition, when electrons and holes are injected into the emission layer they may pass through the emission layer but are then blocked from continuing to pass through the device by an opposite transporting layer, thereby controlling recombination.

The hole transporting layer may be formed using a material such as N,N′-diphenyl-N,N′-bis(1,1′-biphenyl)-4,4′-diamine (“NPB”), N,N′-diphenyl-N,N′-bis (3-methylphenyl)-(1,1′-biphenyl)-4,4′-diamine (“TPD”), and 11,11,12,12-tetracyano-9,10-anthraquinodimethane (disclosed in Synth. Met. 85, 1267 (1997)). The electron transporting layer may be formed using a material such as 3-(4-biphenylyl)-4-phenyl-5-(4-tert-butylphenyl)-1,2,4-triazole (“TAZ”), [2-(4-biphenylyl)-5-(4-tert-butylphenyl)-1,3,4-oxadiazole] (“PBD”), bis (10-hydrozybenzo[h]qinolinatoberyllium) (“Bebq2”), and 2,2,2′-(1,3,5-benzenetriyl)tris-[1-phenyl-1H-benzimidazole] (“TPBI”).

The electron injecting layer 5 may be omitted, but when it is included, a thin layer made of lithium-fluoride (“LiF”) or lithium quinolate (“Liq”) is formed or an alkali metal or alkaline-earth metal such as Li, Ca, Mg, and Sr is used to improve the electron injection efficiency.

A metal such as Ca, Mg, and Al having a low work function is used to form the cathode 6.

As described in the background of the invention, in general, mobility of holes through an organic material is better than mobility of electrons because of ionization potential and electron affinity. The result of which is that holes transfer more easily than electrons. Comparative examples of organic light emitting devices attempt to improve the luminous efficiency of an organic light emitting device by doping an impurity into a hole transporting layer to reduce the mobility of holes. The hole transporting layer has at least two materials; a hole transporting material and an impurity material. The hole transporting material serves as a host material for the impurity. These comparative examples have the problem of conflicting inner and outer electric fields as described in the background of the invention.

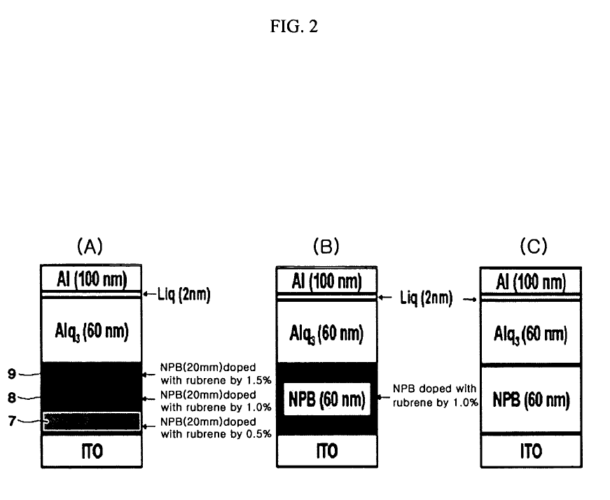

To solve this problem, according to an exemplary embodiment of the present invention, a high efficiency organic light emitting device is created where an impurity is doped with a stepwise concentration suitable for the characteristics of each region in the hole transporting layer. Referring to (A) of FIG. 2 the hole transporting layer consists of three separate regions; an interface region 7, a hole transporting region 8, and another interface region 9. The interface region 7 is located above the anode, shown here in an exemplary embodiment as ITO. The hole transporting region 8 is doped with a low concentration of an impurity for efficient hole injection. In this exemplary embodiment the hole impurity is rubrene. The interface region 9 between the hole transporting layer and the emission layer, shown here in an exemplary embodiment as Alq₃, is doped with a high concentration of an impurity for efficient electron-hole recombination. The hole transporting region 8 interposed between the two interface regions is doped with an impurity with an intermediate concentration between the two impurity concentrations of the above-mentioned interface regions 7 and 9, thereby forming a stepwise impurity concentration gradient in those regions.

Consequently, by adopting a structure where the impurity-doped region in the hole transporting layer is subdivided as described above, an organic light emitting device having improved efficiency and a longer lifespan and which consumes less electric power than a comparative example of an organic light emitting device including a hole transporting layer doped with an impurity with a uniform concentration can be obtained.

The structure of an exemplary embodiment of an organic light emitting device according to the present invention is not particularly limited as long as it comprises two or more regions where the concentration of an impurity doped in the hole transporting layer forms a stepwise concentration gradient. The organic light emitting device may have various structures such as a sequentially stacked structure of a first electrode, a hole transporting layer, an emission layer, an electron transporting layer, an electron injecting layer, and a second electrode; another sequentially stacked structure of a first electrode, a hole injecting layer, a hole transporting layer, an emission layer, an electron transporting layer, an electron injecting layer, and a second electrode; and the other sequentially stacked structure of a first electrode, a hole injecting layer, a hole transporting layer, an emission layer, an electron transporting layer, an electron injecting layer, and a second electrode. In an exemplary embodiment of the present invention, an organic light emitting device has a structure including: an anode formed on a substrate; a hole transporting layer formed on the anode; an emission layer formed on the hole transporting layer; an electron injecting layer formed on the emission layer; and a cathode formed on the electron injecting layer.

A hole transporting layer according to an exemplary embodiment of the present invention comprises two or more regions where the concentration of the doped impurity forms a stepwise concentration gradient, and preferably, the hole transporting layer comprises two or more regions having a stepwise concentration gradient in which the concentration of the doped impurity increases gradually approaching the emission layer. The number of regions may be varied depending on the type and the necessity of the constituent material.

According to an exemplary embodiment of the present invention, an organic light emitting device comprising an interface region between an anode and a hole transporting layer, a hole transporting region, and an interface region between the hole transporting layer and an emission layer is provided.

The impurity concentration in the interface region between the anode and the hole transporting layer, the hole transporting region, and the interface region between the hole transporting layer and the emission layer may be varied according to the type and the number of layers, and the type of impurity used in the doping. The percentage (by weight) of the layer represented by the impurity may be selected from a range of 0.1 weight % to 5 weight %. In an exemplary embodiment of the present invention, NPB as the host material and rubrene as the doped impurity were used, and the hole transporting layer was formed so that the concentrations of rubrene in the interface region between the anode and the hole transporting layer, the hole transporting region, and the interface region between the hole transporting layer and the emission layer were 0.5 weight %, 1.0 weight %, and 1.5 weight %, respectively.

The doped impurity in the hole transporting layer has a higher HOMO energy level than the HOMO energy level of the host material constituting the hole transporting layer. This is because the HOMO energy level of the impurity should be higher in order to trap the holes transferring to the HOMO energy level. Therefore, the impurity may be selected from the group consisting of rubrene (5,6,11,12-tetraphenyl anaphthacene), perylene, 4-dicyano-methylene-2-methyl-6-4-dimethylami-nostyryl-4H-piran (“DCM1”), and 4-(dicyanomethylene)-2-(1-propyl)6-methy 4H-pyran (“DCJTB”).

Also, the thickness of the interface region between the anode and the hole transporting layer, the hole transporting region, and the interface region between the hole transporting layer and the emission layer constituting the hole transporting layer may be varied depending on the type of the material deposited in the layers. According to one exemplary embodiment the total thickness is about 40 nm to about 70 nm. According to another exemplary embodiment the thickness of each region is about 20 nm, to make the total thickness about 60 nm.

By doping an impurity into the host of the hole transporting layer so that a stepwise concentration gradient is formed, as illustrated in FIG. 2 to FIG. 4, the luminous efficiency is improved and malfunctions due to charge trapping by the impurity are reduced or effectively prevented, thereby providing an organic light emitting device having high efficiency where the charge injection and transportation characteristics are improved. In other words, in an organic light emitting device according to an exemplary embodiment of the present invention, impurities in the interface region between the anode and the hole transporting layer trap holes moving therethrough, and the trapped holes block injection and transportation of more holes from the anode to the hole transporting region. Also, the impurities in the interface region between the hole transporting region and the emission layer trap holes moving therethrough. The hole transporting layer also acts as a blocking layer preventing the effective transport of electrons therethrough. The electrons then build up just outside of the hole transporting layer in the emission layer where efficient electron-hole recombination results in improved luminous efficiency.

According to another aspect of the present invention, a manufacturing method of an organic light emitting device comprises: forming an anode on a substrate; forming a hole transporting layer on the anode; forming an emission layer on the hole transporting layer; forming an electron injecting layer on the emission layer; and forming a cathode on the electron injecting layer, wherein the forming a hole transporting layer includes forming two or more regions by deposition so that the concentration of a doped impurity in each region forms a stepwise concentration gradient increasing from region to region.

Hereinafter, a manufacturing method of an organic light emitting device according to an exemplary embodiment of the present invention will be described in detail with reference to the accompanying drawings. The present invention is not limited to the exemplary embodiment mentioned below, but many variations or modifications by those skilled in the present art will be possible and still fall within the spirit and scope of the present invention.

### Exemplary Embodiment 1

### Manufacturing an Organic Light Emitting Device 1

<1-1> Manufacturing an Anode

An ITO thin film having a small sheet resistance (30 ΩΩ/cm²) and a large degree of light transmittance (90%) is deposited on a glass substrate by organic molecular beam deposition.

<1-2> Manufacturing a Hole Transporting Layer

An interface region between an anode and a hole transporting layer is formed with a thickness of 20 nm by deposition of NPB mixed with rubrene so that the doping concentration (determined by weight ratio) of rubrene is 0.5 weight %, in a vacuum condition of 10⁷-10⁻⁹ Torr. Then, a hole transporting region is formed by deposition of NPB mixed with rubrene, the doping concentration of rubrene being 1 weight %. The last interface region between the hole transporting layer and an emission layer is formed with a thickness of 20 nm by deposition of NPB mixed with rubrene, the doping concentration of rubrene being 1.5 weight %, thereby manufacturing a hole transporting layer having a total thickness of 60 nm as shown in FIG. 2 (A).

<1-3> Manufacturing an Emission Layer

In a vacuum condition of 10⁻⁷-10⁻⁹ Torr, an emission layer is formed by vacuum deposition of Alq₃ to a thickness of 60 nm on the manufactured hole transporting layer, with a growing speed of about 0.1 nm/sec.

<1-4> Manufacturing an Liq Electron Injecting Layer and a Cathode

Liq is deposited with a thickness of 2 nm on the manufactured emission layer with a growing speed of about 0.1 nm/sec in a vacuum condition of 10⁻⁷-10⁻⁹ Torr. Thereafter, Al is deposited with a thickness of 100 nm as the cathode.

### COMPARATIVE EXAMPLE 1

### Manufacturing an Organic Light Emitting Device Including a Hole Transporting Layer Uniformly Doped with an Impurity

An organic light emitting device, as shown in (B) of FIG. 2, is manufactured in the same way as the Exemplary Embodiment 1, except that a hole transporting layer having a thickness of 60 nm is manufactured by deposition of NPB mixed with rubrene as the impurity where the doping concentration of rubrene is maintained to be 1.0 weight %.

### COMPARATIVE EXAMPLE 2

### Manufacturing an Organic Light Emitting Device Including a Hole Transporting Layer not Doped with an Impurity

An organic light emitting device, as shown in (C) of FIG. 2, is manufactured in the same way as the exemplary embodiment 1, except that a hole transporting layer is manufactured by deposition of NPB with a thickness of 60 nm. The hole transporting layer in this comparative example is not doped with rubrene.

### EXPERIMENTAL EXAMPLE 1

### Comparison of Efficiency of an Organic Light Emitting Device

<1-1> Current Density-Voltage Measurement of an Organic Light Emitting Device

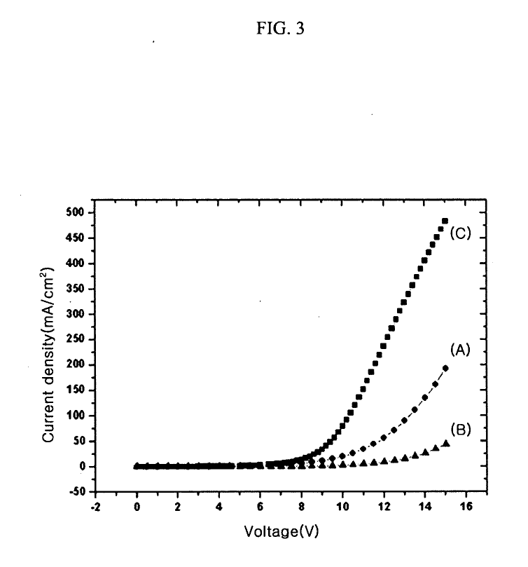

To compare the efficiency of an exemplary embodiment of an organic light emitting device according to the present invention, as shown in (A) of FIG. 2, with the efficiency of comparative examples 1 and 2 of organic light emitting devices as shown in (B) and (C) of FIG. 2, current density-voltage measurement was performed while varying the voltage from 0 V to 15 V by units of 0.5 V using a Source-Measure Unit, model 236, manufactured by Keithley Instruments Inc. (hereinafter, “the Keithley”). As shown in FIG. 3, at a voltage of 15 V, the devices of (A), (B) and (C) of FIG. 2 show current densities of 192 mA/cm², 44 mA/cm², and 483 mA/cm², respectively. That is, while the charge injection and transportation characteristics of the devices (A) and (B) which are doped with an impurity are deteriorated compared to the device (C) which is not doped with an impurity, it is shown that the charge injection and transportation characteristics of the organic light emitting device (A) in which an impurity is doped to form a stepwise concentration gradient are improved compared to the organic light emitting device (B) which is uniformly doped with an impurity. The reduced charge injection and transportation characteristics of the devices (A) and (B) are due to the multi-layered structure having a subdivided region where an impurity is doped into a host, thereby reducing the charge trap by the impurity in the hole transporting layer.

<1-2> Luminance-Voltage Measurement of an Organic Light Emitting Device

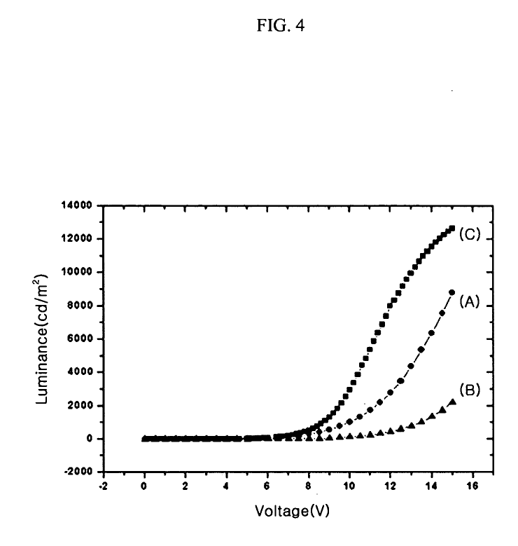

Luminance was measured with a luminance meter, particularly the Chroma Meter CS-100A, manufactured by Konica Minolta, within a dark box while applying voltages from 0 V to 15 V to the anode and the cathode of a manufactured organic light emitting device using the Keithley. FIG. 4 is a graph illustrating the result. Under a voltage of 15 V, luminances of devices (A), (B) and (C) were 8790 cd/m², 2210 cd/m², and 12,650 cd/m² respectively, and the turn-on voltages where light emitting starts were 3.5 V, 5 V, and 3 V, respectively. That is, compared to the organic light emitting device (B) doped with an impurity according to the comparative example, the organic light emitting device (A) including a hole transporting layer according to an embodiment of the present invention shows a higher luminance and a lower turn-on voltage.

<1-3> Efficiency-Current Density of an Organic Light Emitting Device

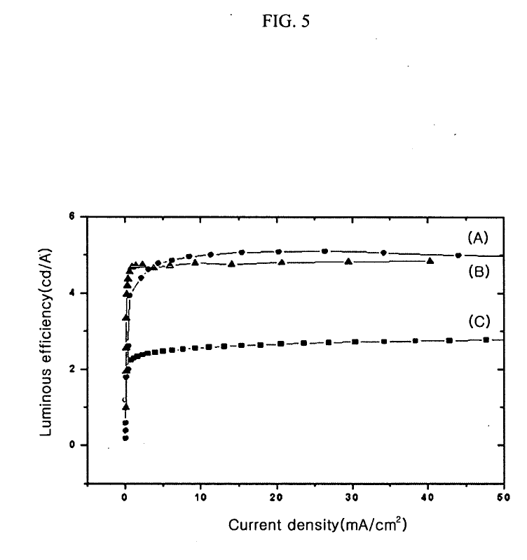

FIG. 5 is a graph illustrating current density versus luminous efficiency of an organic light emitting device. The devices (A), (B), and (C) of FIG. 2 show a steady luminous efficiency of 5.1 cd/A, 4.8 cd/A, and 2.7 cd/A after the current density is increased over 10 mA/Cm², respectively. The above results show that the luminous efficiency is improved when an impurity is doped into the hole transporting layer as comparative example (B) has a higher luminous efficiency than that of comparative example (C). Therefore, in an organic light emitting device according to an exemplary embodiment of the present invention, by adopting a hole transporting layer having a multi-layered structure formed by subdividing the impurity-doped region, luminous efficiency is improved even further and a charge trap by the impurity is suppressed, thereby obtaining a low turn-on voltage high luminance characteristics.

<1-4> Comparison of Color Coordinates

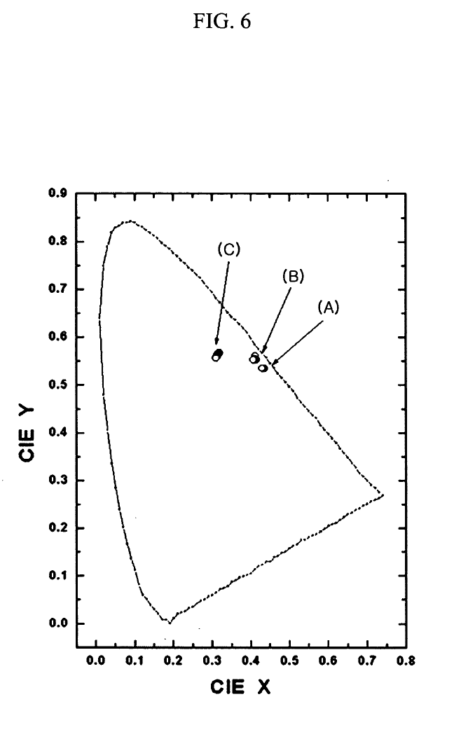

FIG. 6 shows that the devices of (A), (B), and (C) have color coordinates of (0.43, 0.53), (0.41, 0.55), and (0.31, 0.56), respectively. Each circle on the graph corresponds to a color coordinate for a given structure at a given voltage. Therefore, each cluster of circles represents the range of colors output by each device for a given range of voltages. The above result shows that an organic light emitting device according to an exemplary embodiment of the present invention emits a yellow color, and it emits a stable yellow color even under a variation of voltage by doping an impurity.

As described above, an organic light emitting device according to an exemplary embodiment of the present invention uses a hole transporting layer including two or more regions deposited with a concentration of an impurity which varies stepwise, thereby improving luminous efficiency and reducing a driving voltage as well as facilitating light emitting with color stability.

While the present invention has been described in connection with what is presently considered to be practical exemplary embodiments, it is to be understood that the present invention is not limited to the disclosed exemplary embodiments, but, on the contrary, is intended to cover various modifications and equivalent arrangements included within the spirit and scope of the appended claims.

What is claimed is:

1. An organic light emitting device comprising:
a hole transporting layer including two or more regions in which concentration of an impurity doped into a host forms a stepwise concentration gradient.

2. The organic light emitting device of claim 1, further comprising:
an anode formed on a substrate;
an emission layer formed on the hole transporting layer;
an electron injecting layer formed on the emission layer; and
a cathode formed on the electron injecting layer,
wherein the hole transporting layer is formed on the anode.

3. The organic light emitting device of claim 2, wherein the hole transporting layer comprises an interface region between an anode and a hole transporting region, the hole transporting region, and an interface region between an emission layer and the hole transporting region.

4. The organic light emitting device of claim 3, wherein the impurity concentration doped into the interface region between the anode and the hole transporting region is about 0.5 weight %, the impurity concentration doped into the hole transporting region is about 1.0 weight %, and the impurity concentration doped into the interface region between the emission layer and the hole transporting region is about 1.5 weight %.

5. The organic light emitting device of claim 3, wherein the thickness of the interface region between the anode and the hole transporting region, the thickness of the hole transporting region, and the thickness of the interface region between the emission layer and the hole transporting region is about 20 nm, respectively.

6. The organic light emitting device of claim 3, wherein the thickness of the hole transporting layer is about 40 nm to about 70 nm.

7. The organic light emitting device of claim 2, wherein the impurity has a higher highest occupied molecular orbital (HOMO) energy level than a HOMO energy level of a material constituting the hole transporting layer.

8. The organic light emitting device of claim 7, wherein the impurity is at least one selected from a group of rubrene, perylene 4-dicyano-methylene-2-methyl-6-4-dimethylami-nostyryl-4H-piran (DCM1) and 4-(dicyanomethylene)-2-(1-propyl)6-methy 4H-pyran (DCJTB).

9. The organic light emitting device of claim 1, wherein the impurity has a higher highest occupied molecular orbital (HOMO) energy level than a HOMO energy level of a material constituting the hole transporting layer.

10. The organic light emitting device of claim 9, wherein the impurity is at least one selected from a group of rubrene, perylene 4-dicyano-methylene-2-methyl-6-4-dimethylami-nostyryl-4H-piran (DCM1), and 4-(dicyanomethylene)-2-(1-propyl)6-methy 4H-pyran (DCJTB).

11. A manufacturing method of an organic light emitting device comprising:
forming an anode on a substrate;
forming a hole transporting layer on the anode;
forming an emission layer on the hole transporting layer;
forming an electron injecting layer on the emission layer; and
forming a cathode on the electron injecting layer,
wherein the forming a hole transporting layer includes two or more regions formed by deposition in which the concentration of a doped impurity forms a stepwise concentration gradient.
